(19) United States
(12) Patent Application Publication
(10) Pub. No.: US 2002/0044421 A1
(43) Pub. Date: Apr. 18, 2002

(54) Extractable temperature-controlled fan device with fault-tolerable ability

(75) Inventor: Chich-Chung Cheng, Shu-Lin City (TW)

Correspondence Address: DOUGHERTY & TROXELL, SUITE 1404, 5205 LEESBURG PIKE, FALLS CHURCH, VA, 22041, US

(73) Assignee: Countless Ages Industrial Co., Ltd.

(21) Appl. No.: 09/929,013

(22) Filed: Aug. 15, 2001

(30) Foreign Application Priority Data
Jun. 1, 2001 (TW) 090209041

(51) Int. Cl. H05K 5/00

(52) U.S. Cl. 361/687; 361/695

(57) ABSTRACT

An extractable temperature-controlled fan device with fault-tolerable ability is installed with disk drives, power supplies or other computer peripherals. It is unnecessary to stop the operation of a mainframe or a power supply box, the extractable fan case is replaceable; and the installing position of the extractable fan case is adjustable in response to features of the mainframe or the disk drive or power supply box. An independent extractable fan case is installed with at least one fan. By a preset space at one side of a disk drive or power supply box, the extractable fan case can be updated. Therefore, the extractable temperature-controlled fan device can be updated without needing to stop the operation of the mainframe.

### BACKGROUND OF THE INVENTION

1. Field of the Invention

The present invention relates to a fan device, and especially to an extractable temperature-controlled fan device with fault-tolerable ability.

2. Description of Related Art

Because of the current trend in the electronic technology, more and more elements are equipped in a device for performing various works, such as data reading, logic operation, or data input/output. Furthermore, the speed of the CPU is increased, and thus more heat is generated. All these factors cause the temperature of an electronic device to increase rapidly, and therefore, heat dissipation becomes an important problem which is necessary to be solved, otherwise the operation of the computer will be affected dramatically.

In general, heat dissipating fans are used to effectively control the temperature of electronic or electric products. By fans, outer cool air is extracted into the device and hot air is dissipated. The fans are easily destroyed due to the quality, environment, or lifetime of the fans. Generally, in the updating work of a fan, most of the mainframe, such as a computer servo or a network mainframe, must be stopped for updating. However, some special mainframes, such as computer servos or network mainframes are not suitable to be stopped as desired. Therefore, there is an eager demand for a novel design which may improve the prior art defect.

### SUMMARY OF THE INVENTION

Accordingly, the primary object of the present invention is to provide an extractable temperature-controlled fan device with fault-tolerable ability, wherein it is unnecessary to stop the operation of a mainframe or a power supply box, the extractable fan case is replaceable. Power of the extractable fan case is actuated or closed automatically. The fans in the extractable fan case are modularized. The installing position of the extractable fan case is adjustable in response to features of the mainframe or the disk drive or power supply box. Thereby, the heat from the fans may be blown forwards, or backwards or sideward.

Another object of the present invention is to provide an extractable temperature-controlled fan device with fault-tolerable ability, wherein as one of the at least two fans in the extractable fan case is actuated, then fan can be actuated immediately and then operate continuously so as to maintain a general heat dissipation function. Each fan can be set with a respective actuating temperature. When the temperature of a computer casing does not achieve the set temperature, the other fan is not actuated. Therefore, power is saved and the lifetime of the fan is prolonged. If the temperature in the casing achieves a set temperature, the other fan will be actuated for enhancing the power dissipation effect. After the temperature in the casing is decreased to be below the set value, then the fan will close automatically.

A further object of the present invention is to provide an extractable temperature-controlled fan device with fault-tolerable ability, wherein a fan auto detection function is utilized. When one fan is destroyed, other than an alarm is emitted, another fan will be actuated for replacing other fan and the heat dissipation function can be retained in normal operation. The extractable fan case of the present invention is adjustable with the structure of the mainframe and the disk drive or power supply box.

The various objects and advantages of the present invention will be more readily understood from the following detailed description when read in conjunction with the appended drawing.

### BRIEF DESCRIPTION OF THE DRAWINGS

FIG. 1 is a perspective view of the embodiment in the present invention.

FIG. 2 is a lateral view of the embodiment in the present invention.

FIG. 3 is an exploded perspective view of the embodiment in the present invention.

### DETAILED DESCRIPTION OF THE PREFERRED EMBODIMENTS

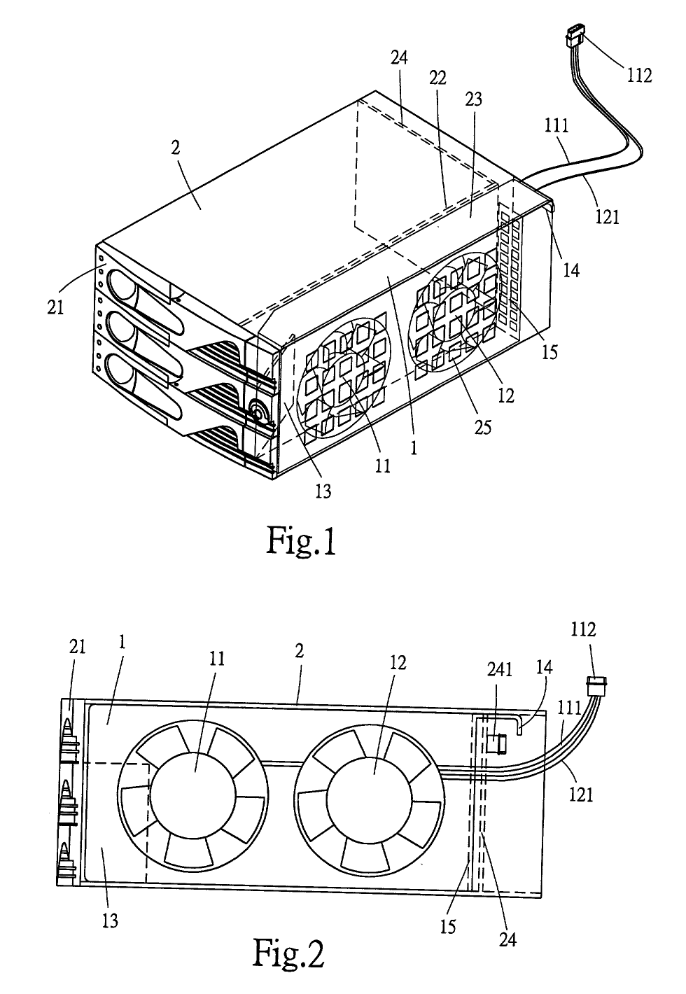

Referring to FIGS. 1 to 3, the present invention mainly includes an independent extractable fan case 1 with one or more fans 11, 12 being placed therein. The upper edge of the rear side thereof has a handle 14. A screening plate 15 is placed near the distal end. The power wires 111, 121 of the fans 11 and 12 in the extractable fan case 1 can be guided to the rear side of the extractable fan case 1. The ends of the power wire 111 and power wire 121 are installed with terminals.

A disk drive or power supply box 2 with respect to the extractable fan case 1 is installed. The fixed type or extractable type disk drive or a power supply 21 is installed in the box 2. A metal spacer 22 is placed in the interior of the box 2 so as to form a space 23, thereby, the extractable fan case 1 may be pushed into the space 23. Vents 25 are formed at positions corresponding to the fans 11, 12. Thereby, the heat from the fans may be blown forwards, or backwards or sideward.

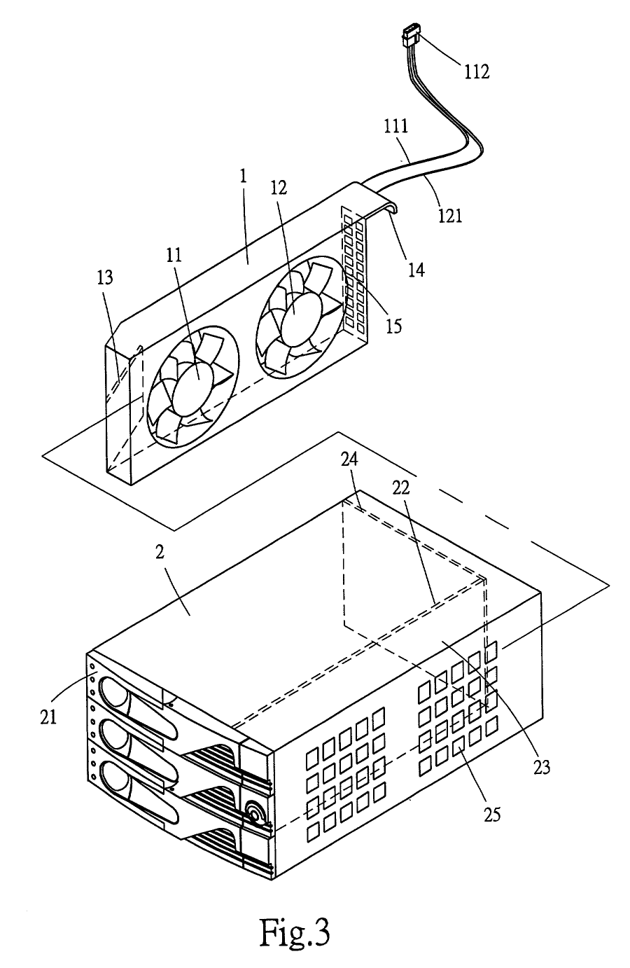

With reference to FIGS. 2 and 3, to realize the present invention, the front end of the extractable fan case 1 is inserted into the box 2 from the opening at the space 23. Then the expandable sheet 13 resists against the metal spacer 22. In one aspect, a grounding effect is formed. In another aspect, the fixing and the tightness of contact are enhanced. When the extractable fan case 1 is pushed toward a predetermined position, the connecting terminal 112 of the power wire 111 and power wire 121 is inserted into a connecting terminal 241 on the back plate 24 of the disk drive or power source box 2, thereby, power is conducted and supplied so as to actuate the fans 11 and 12.

When the mainframe, or disk drive or power supply box 2 is in operation, once any one of the fans is destroyed, it is needless to stop the mainframe or disk drive or power supply box 2. Then the connecting terminals 112 and 241 are separated from the rear side of the disk drive or power supply box 2, thereby, the extractable fan case 1 can be updated without needing to stop the operation.

As one of the at least two fans 11, 12 in the extractable fan case 1 is actuated, then fan 11 can be actuated immediately and then operate continuously so as to maintain a general heat dissipation function. Each fan can be set with a respective actuating temperature. When the temperature of a computer casing does not achieve the set temperature, the other fan 12 is not actuated. Therefore, power is saved and the lifetime of the fan is prolonged. If the temperature in the casing achieves a set temperature, the other fan 12 will be actuated for enhancing the power dissipation effect. After the temperature in the casing is decreased to be below the set value, than the fan 12 will close automatically.

In the present invention, a fan auto detection function is utilized. When one fan is destroyed, other than an alarm is emitted, another fan will be actuated for replacing other fan and the heat dissipation function can be retained in normal operation. The extractable fan case of the present invention is adjustable with the structure of the mainframe and the disk drive or power supply box.

The present invention are thus described, it will be obvious that the same may be varied in many ways. Such variations are not to be regarded as a departure from the spirit and scope of the present invention, and all such modifications as would be obvious to one skilled in the art are intended to be included within the scope of the following claims.

What is claimed is:

1. An extractable temperature-controlled fan device with fault-tolerable ability comprising:
an extractable fan case having at least one fan installed therein;
a disk drive or power supply box, one lateral side of the disk drive or power supply box having a predetermined space, thereby, the extractable fan case being inserted into the space;
wherein the extractable fan case is replaceable without needing to stop an operation of a mainframe or a power supply box,; and an installing position of the extractable fan case is adjustable in response to features of the mainframe or the disk drive or power supply box.

2. The extractable temperature-controlled fan device with fault-tolerable ability as claimed in claim 1, wherein an inner edge of a front side of the extractable fan device has an expandable sheet, and an upper edge of a rear side is installed with a handle; a distal end of the extractable fan case has a screening plate; power wires of the fans in the extractable fan case are guided to a rear side of the extractable fan case; wire ends of the power wires are installed with terminals; a fixed type or extractable type disk drive or a power supply is installed in the box; a metal spacer is placed in an interior of the box so as to form a space, thereby, the extractable fan case is pushed into the space; vents are formed at positions corresponding to the fans; thereby, the heat from the fans is blown forwards, or backwards or sideward.

3. The extractable temperature-controlled fan device with fault-tolerable ability as claimed in claim 1, wherein a connecting terminal of the power wires is inserted into a connecting terminal on the back plate of the disk drive or power source box, thereby, power is turned on and supplied to actuate the fans.

4. The extractable temperature-controlled fan device with fault-tolerable ability as claimed in claim 1, wherein fans in the extractable fan case has a fan auto detection function; as one fan is destroyed, other than an alarm is emitted, another fan will be actuated for replacing the destroyed fan, thereby, maintaining a normal heat dissipating function.
